(19) United States
(12) Patent Application Publication
(10) Pub. No.: US 2026/0005133 A1
(43) Pub. Date: Jan. 1, 2026

(54) INTEGRATED MMC PACKAGE WITH INDUCTOR AND DIE

(71) Applicant: Texas Instruments Incorporated, Dallas, TX (US)

(72) Inventors: Eugene Lee, Cheras (MY); Sylvester Ankamah-Kusi, McKinney, TX (US); Rajen Murugan, Dallas, TX (US); Harshpreet Bakshi, Dallas, TX (US)

(21) Appl. No.: 18/759,413

(22) Filed: Jun. 28, 2024

(51) Int. Cl. H01L 23/522; H01F 27/29; H01L 23/00; H01L 23/29; H01L 23/31; H01L 23/498; H05K 1/18

(52) U.S. Cl. CPC H01L 23/5227; H01F 27/29; H01L 23/29; H01L 23/3121; H01L 23/49838; H05K 1/181; H10D 1/20; H01L 24/08; H01L 24/32; H01L 2224/08225; H01L 2224/32225; H01L 2924/19042

(57) ABSTRACT

An electronic device includes a first metal structure with a first coil extending in a first plane and a first coil terminal, a second metal structure with a second coil extending in a second plane and a second coil terminal, the second plane approximately parallel to the first plane, a semiconductor die with die terminals and opposite first and second sides, the first side attached to the first metal structure and the die terminals extending outward from the second side to a parallel third plane, and a molded magnetic package structure enclosing portions of the first and second coils and a portion of the semiconductor die, wherein the die terminals and the first and second coil terminals are exposed outside the molded magnetic package structure along the third plane.

### BACKGROUND

Switching circuits are used in a variety of system applications such as power converters, and often include one or more transistors and magnetic components. For example, buck, boost, buck-boost, cuk and other DC to DC converters often include an inductor, transformer, or other magnetic component along with transistors operated as switches. Conventional power converters provide transistor switches in the form of a packaged electronic device that is soldered to a circuit board and a switching node of the transistor configuration is connected to a separate inductor component that is also soldered to the circuit board. However, the separate transistor and magnetic devices occupy valuable space on a system circuit board, and external inductor components can affect noise performance of the system through high frequency switching operation of the converter transistors.

### SUMMARY

In one aspect, an electronic device includes first and second metal structures, a semiconductor die, and a molded magnetic package structure. The first metal structure has a first coil extending in a first plane and a first coil terminal, and the second metal structure has a second coil extending in a parallel second plane and a second coil terminal. The semiconductor die has die terminals and opposite first and second sides, with the first side attached to the first metal structure and the die terminals extending outward from the second side to a parallel third plane. The molded magnetic package structure encloses portions of the first and second coils and a portion of the semiconductor die, with the die terminals and the first and second coil terminals exposed outside the molded magnetic package structure along the third plane.

In another aspect, a system includes a circuit board and an electronic device. The electronic device includes first and second metal structures, a semiconductor die, and a molded magnetic package structure. The first metal structure has a first coil extending in a first plane and a first coil terminal, and the second metal structure has a second coil extending in a parallel second plane and a second coil terminal. The semiconductor die has die terminals and opposite first and second sides, with the first side attached to the first metal structure and the die terminals extending outward from the second side to a parallel third plane. The molded magnetic package structure encloses portions of the first and second coils and a portion of the semiconductor die, with the die terminals and the first and second coil terminals exposed outside the molded magnetic package structure along the third plane and are attached to respective conductive traces of the circuit board.

In a further aspect, a method of fabricating an electronic device includes attaching first and second lead frames to one another with respective first and second coils in respective first and second parallel planes, attaching a semiconductor die backside to the first coil, and molding a magnetic package structure to enclose the first and second coils and a portion of the semiconductor die and to expose die terminals of a front side of the semiconductor die and first and second coil terminals of the first and second lead frames outside the molded magnetic package structure along a third plane that is parallel to the first and second planes.

### BRIEF DESCRIPTION OF THE DRAWINGS

FIG. 1 is a partial sectional side elevation view taken along line 1-1 of FIGS. 1A and 1B of a power conversion system including an electronic device having two metal structures and corresponding coils in a magnetic molded structure with exposed terminals soldered to a circuit board.

FIG. 1A is a partial sectional top view of the electronic device taken along line 1A-1A of FIGS. 1 and 1C.

FIG. 1B is a partial sectional top view of the electronic device taken along line 1B-1B of FIGS. 1 and 1C.

FIG. 1C is a partial sectional side elevation view taken along line 1C-1C of FIGS. 1A and 1B.

FIG. 1D is a simplified schematic diagram of electronic components of the electronic device of FIGS. 1-1C having first and second coils connected to form an inductor.

FIG. 1E is a simplified schematic diagram of electronic components of another example electronic device of FIGS. 1F-1I having first and second coils forming primary and secondary windings of a transformer.

FIG. 1F is a partial sectional side elevation view taken along line 1F-1F of FIGS. 1G and 1H of a power conversion system including the electronic device with first and second coils forming primary and secondary windings of a transformer.

FIG. 1G is a partial sectional top view of the electronic device taken along line 1G-1G of FIGS. 1F and 1I.

FIG. 1H is a partial sectional top view of the electronic device taken along line 1H-1H of FIGS. 1F and 1I.

FIG. 1I is a partial sectional side elevation view taken along line 1I-1I of FIGS. 1G and 1H.

FIG. 1J is a partial sectional side elevation view of a power conversion system including another electronic device having three metal structures and three corresponding coils in a magnetic molded structure with exposed terminals soldered to a circuit board.

FIG. 2 is a flow diagram of a method of manufacturing an electronic device.

FIGS. 3-7A are side and bottom views of the example electronic device of FIGS. 1-1D undergoing fabrication processing according to an implementation of the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various disclosed structures and methods of the present disclosure may be beneficially applied to manufacturing an electronic device such as an integrated circuit. While such examples may be expected to provide various improvements, no particular result is a requirement of the present disclosure unless explicitly recited in a particular claim.

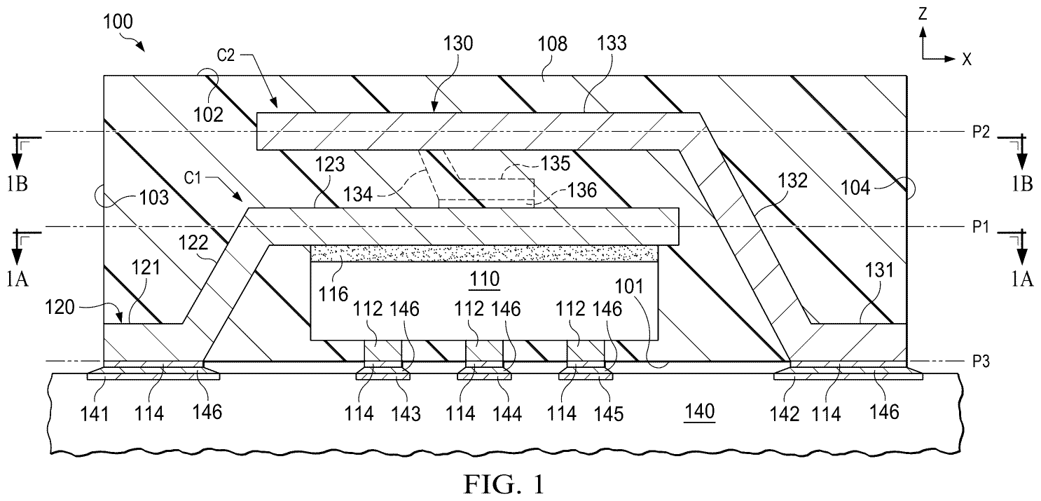

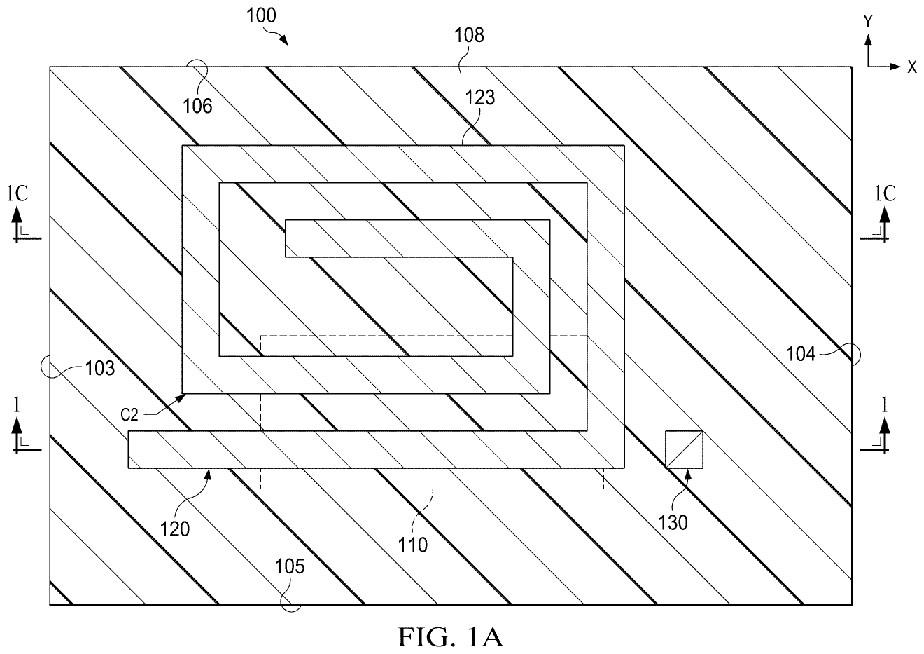

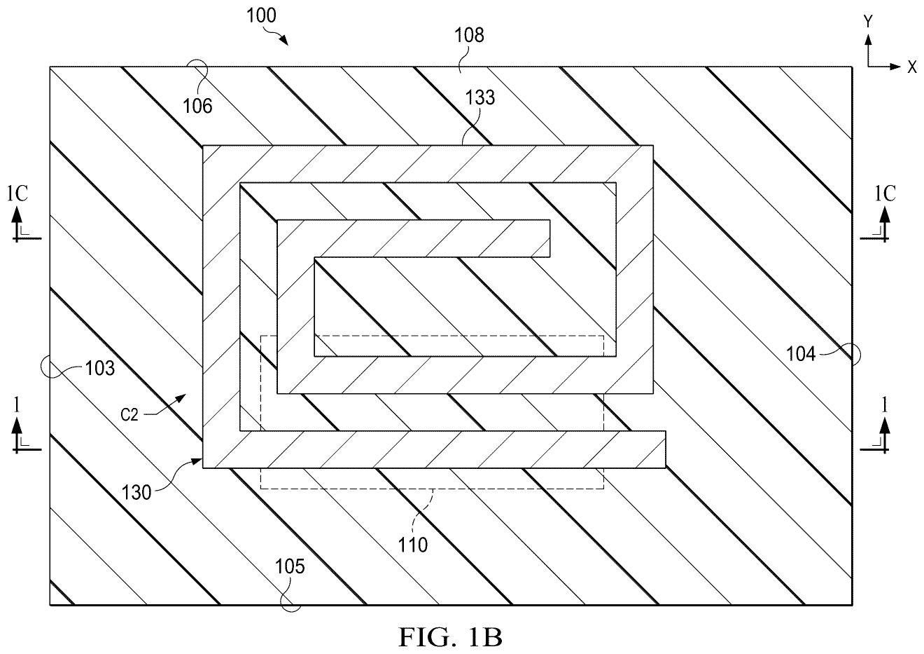

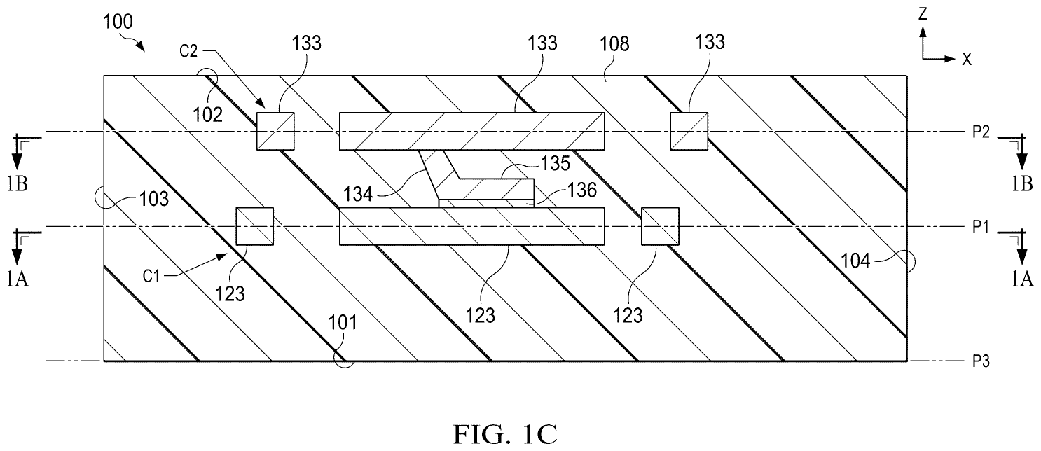

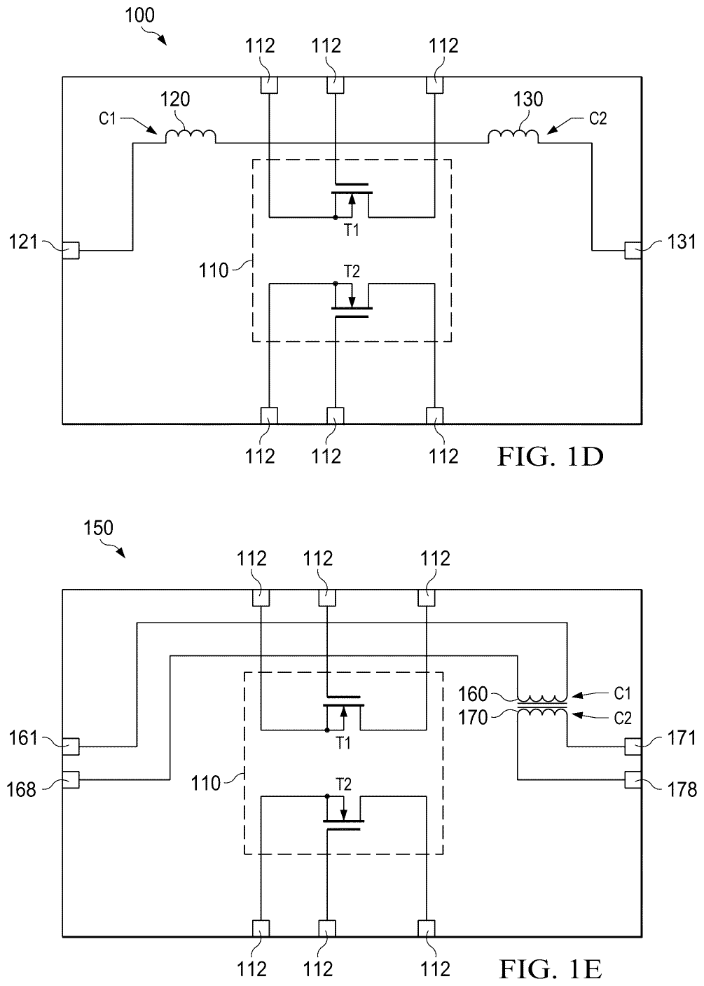

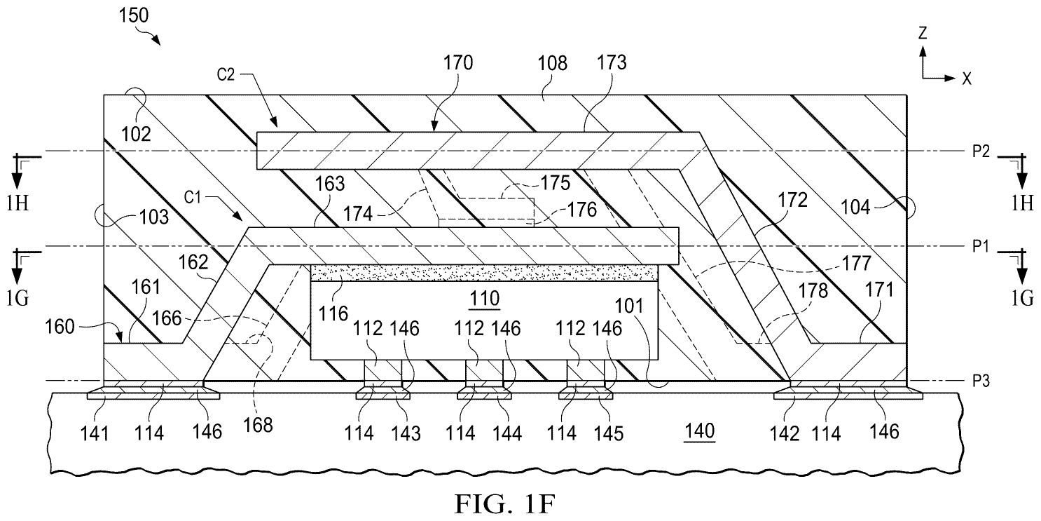

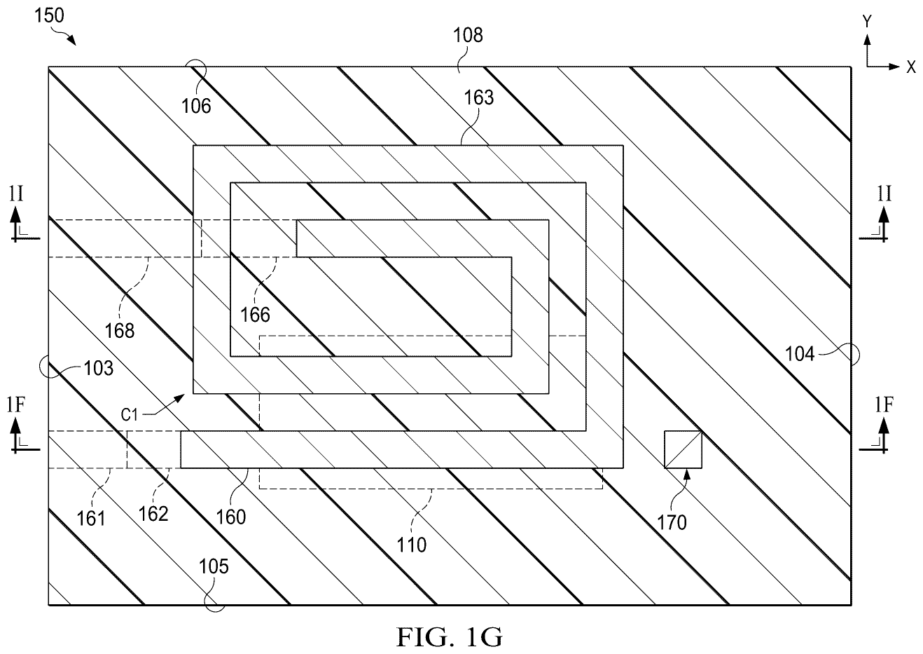

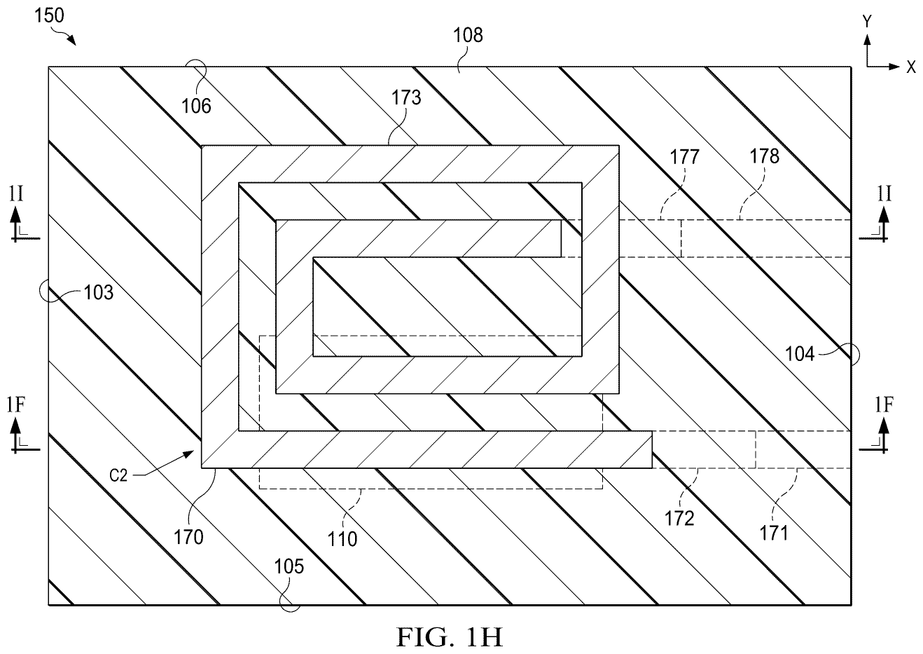

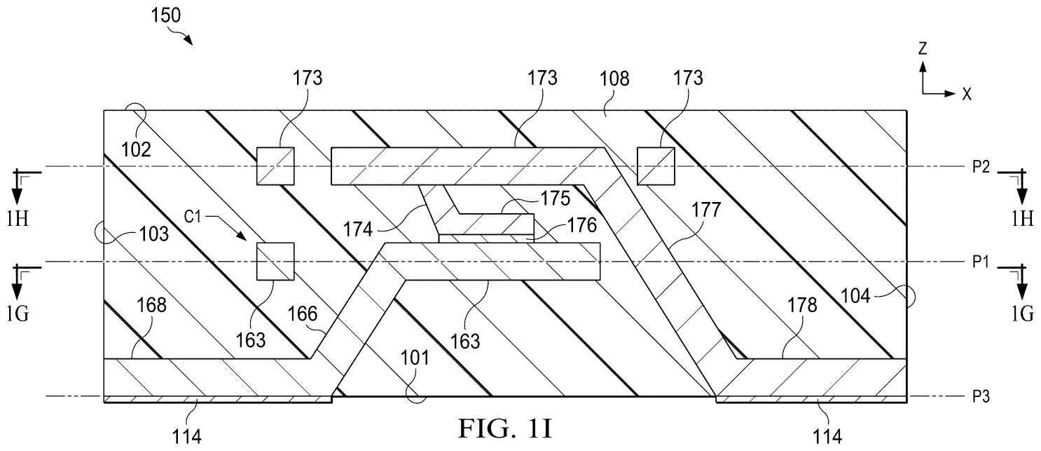

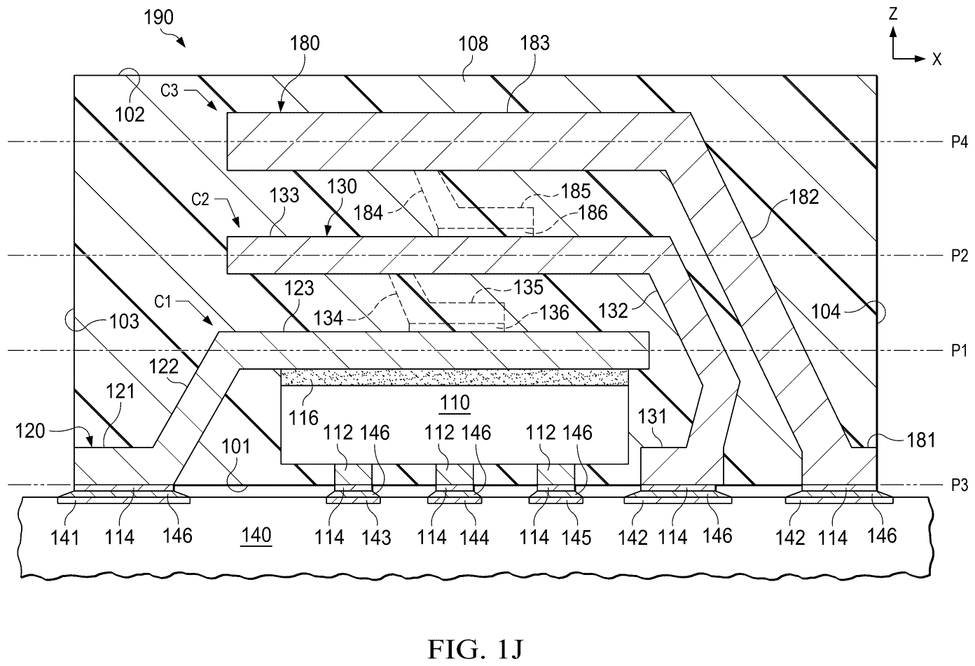

FIGS. 1-1D show a compact electronic device 100 having switching transistors and an inductor formed by first and second coils C1 (FIGS. 1, 1A, 1C, and 1D) and C2 (FIGS. 1 and 1B-1D) integrated in a single package to conserve space and reduce cost in a power conversion system. FIG. 1 shows a side section view of the electronic device 100 taken along line 1-1 of FIGS. 1A and 1B and FIG. 1A shows a top section view illustrating the first coil C1 along line 1A-1A of FIGS. 1 and 1C. FIG. 1B shows a top section view of the second coil C2 along line 1B-1B of FIGS. 1 and 1C. FIG. 1C shows a down set tab connecting the two coils in a side section view along line 1C-1C of FIGS. 1A and 1B. FIG. 1D schematically illustrates the electronic components of the electronic device 100.

The electronic device 100 is illustrated in FIGS. 1-1C in an example three-dimensional space with a first direction X, a perpendicular (orthogonal) second direction Y (FIGS. 1A and 1B), and a third direction Z (FIGS. 1 and 1C) that is perpendicular (orthogonal) to the respective first and second directions X and Y. Structures or features along any two of these directions are orthogonal to one another. As shown in FIGS. 1 and 1C, the electronic device 100 has opposite first and second sides 101 and 102 (e.g., bottom and top), respectively, which are spaced apart from one another along the third direction Z in the illustrated position. The electronic device 100 also has laterally opposite third and fourth sides 103 and 104 (FIGS. 1-1C) that are spaced apart from one another along the first direction X, and fifth and sixth sides 105 and 106 (FIGS. 1A and 1B) that are spaced apart from one another along the second direction Y in the illustrated position.

A molded magnetic package structure 108 encloses portions of the first and second coils C1 and C2 and a portion of a semiconductor die 110 (FIG. 1). The molded magnetic package structure 108 in one example is generally rectangular and defines approximately planar top and lateral sides 102-106, although not a requirement of all possible implementations. The molded magnetic package structure 108 in one example is formed of magnetic molding compound, sometimes referred to as magnetic mold compound, which provides magnetic coupling for the coils C1 and C2. In one example, the coils C1 and C2 are connected to form an inductor as schematically illustrated in FIG. 1D. In another example, the coils C1 and C2 are electrically isolated from one another and can be used as primary and secondary windings of a transformer (e.g., FIGS. 1E-1I below).

In one example, the packaged electronic device 100 has a no lead package shape, such as a dual flat no lead (DFN) shape with die terminals 112 exposed outside the molded magnetic package structure 108 along the bottom or first side 101 and coil terminals 121 and 131 exposed along the first side 101 and along the respective lateral sides 103 and 104 as shown in FIG. 1. The semiconductor die 110 can include one or more electronic components, such as transistors, resistors, capacitors, diodes, etc. The illustrated example has first and second transistors T1 and T2 in the semiconductor die 110 as schematically illustrated in FIG. 1D. In other examples, the packaged electronic device 100 can include more than one semiconductor die.

The die terminals 112 in this example provide external connectivity for gate, drain and source terminals of the transistors T1 and T2, for example, to allow interconnection in a half bridge or other desired circuit arrangement by conductive traces of a host circuit board along with an inductor formed by the interconnected coils C1 and C2 via coil terminals 121 and 131 to form a DC to DC converter or other system. In the example of FIG. 1, the die terminals 112 and the coil terminals 121, 131 have respective plated surfaces 114 exposed outside the molded magnetic package structure 108 along the first side 101 to allow soldering to a circuit board 140. Any suitable conductive material can be used for the plated surfaces 114. In another example, the plated surfaces 114 can be omitted.

The example electronic device 100 has an integrated inductor magnetic component formed using magnetic mold compound of the package structure 108, along with the component or components of the semiconductor die 110. The die components and the integrated inductor have terminals 112, 121 and 131 that allow application-specific interconnection of the components in a desired circuit configuration by design of the host circuit board 140 and the conductive traces thereof. The integration of the magnetic component helps to reduce electronic system size and increase power density and can be used in low or high voltage applications. The proximity of the semiconductor die 110 to metal structures used in forming the coils C1 and C2 can help reduce electromagnetic interference (EMI) in operation of the electronic device 100 to provide improved inductance performance while reducing system cost and space.

As shown in FIGS. 1, 1A and 1C, the first coil C1 is formed by a first metal structure 120 with a first portion forming the first coil terminal 121, a second portion 122 that extends from the first portion 121 (FIG. 1) to a third portion 123 that includes the first coil C1 extending in a first plane P1 (e.g., a first X-Y plane in the illustrated orientation). The first coil C1 has a first end that is electrically connected to the first coil terminal 121 by the second portion 122. As shown in FIGS. 1, 1A, and 1C, the third portion 123 of the first coil C1 includes turns, and the turns of the first coil C1 extend within the first plane P1 indicated in FIGS. 1 and 1C. Any suitable number and shape of turns can be used for either or both coils C1 and C2 in various implementations. The illustrated example has turns with portions and 90 degree angles with generally uniform widths. Other designs can be used, including spiral turns, turns with rounded features and/or nonuniform widths.

As shown in FIGS. 1, 1B and 1C, the electronic device 100 also has a second metal structure 130 with the second coil C2 extending in a second plane P2 that is approximately parallel to the first plane P1. The second metal structure 130 includes a first portion that forms the second coil terminal 131, a second portion 132 that extends from the first portion 131 to a third portion 133 that includes the second coil C2 with turns in the second plane P2. The turns of the second coil C2 in the illustrated example are coiled in clockwise fashion in the top view of FIG. 1B, and the turns of the first coil C1 in FIG. 1A are coiled in counterclockwise fashion in the top view of FIG. 1A. In another example, the turns of the first and second coil C1 and C2 can be coiled in the same direction (e.g., clockwise or counterclockwise in the illustrated top views). In one example, the second metal structure 130 includes fourth and fifth portions 134 and 135 (shown in FIG. 1C and shown in phantom lines in FIG. 1) that form a downwardly extending tab, which can also be referred to as a “down set” feature of the second metal structure 130.

In the illustrated example, the first metal structure 120 is attached to the second metal structure 130 by the tab 134, 135 of the second metal structure 120 by a conductive material 136 that electrically connects the first and second coils C1 and C2 to one another to form an inductor. In one implementation, the conductive material 136 is or includes solder, and the down set tab 134, 135 is connected to the first metal structure 120 by the solder 136. In another implementation, the conductive material 136 is or includes an electrically conductive adhesive. The down set tab feature 134, 135 and the conductive material 136 help position the first and second metal structures 120 and 130 along the third direction Z during manufacturing, as well as providing an electrical connection between the first and second coils C1 and C2 to form an integrated inductor in the electronic device 100. In another example, the first and second metal structures 120 and 130 can be structurally attached to one another by an upset or down set feature (e.g., a tab) of one of the metal structures 120 or 130 that extends between the first and second planes P1 and P2 using solder or a conductive adhesive to electrically connect the coils C1 and C2 to one another. The tab 134, 135 in the illustrated example electrically connects the first coil C1 to the second coil C2 to form the integrated inductor between the first and second coil terminals 121 and 131.

In a further example, the first and second metal structures 120 and 130 can be structurally attached to one another by an upset or down set feature (e.g., a tab) of one of the metal structures 120 or 130 that extends between the first and second planes P1 and P2 using a non-conductive adhesive (e.g., epoxy, etc.) to provide magnetic coupling between the coils C1 and C2 without internal electrical connection between the coils C1 and C2. For example, the first and second metal structures 120 and 130 can include coils C1 and C2 that individually have first and second ends connected to respective coil terminals and exposed along the first side 101 for soldering to a host circuit board that can provide traces to electrically connect the ends of the respective coils C1 and C2 in series to form an integrated inductor or to form primary and secondary windings of an integrated transformer (e.g., FIGS. 1E-1I below).

As shown in FIG. 1, the semiconductor die 110 has an upper or first side attached to the first metal structure 120 using an adhesive 116, such as a die attach film or die attach material, for example, a nonconductive epoxy. In the illustrated example, the first side of the semiconductor die 110 is attached to a bottom side of the third portion 123 of the first metal structure 120. An opposite bottom or second side of the semiconductor die 110 includes the die terminals 112. The die terminals 112 extend outward from the second side along the third direction Z to a third plane P3 that is parallel to the first and second planes P1 and P2. As shown in FIG. 1, the molded magnetic package structure 108 encloses portions of the first and second coils C1, C2 and a portion of the semiconductor die 110. In addition, the die terminals 112 and the first and second coil terminals 121 and 131 are exposed outside the molded magnetic package structure 108 along the third plane P3. The relative positioning of the first and second metal structures 120 and 130 and the semiconductor die 110 provide approximately coplanar exposed surfaces of the terminals 112, 121 and 131 along the third plane P3 to provide electrical conductivity of the coils C1, C2 and the component or components of the semiconductor die 110 to the host circuit board 140.

The circuit board 140 in the example of FIG. 1 includes conductive traces 141, 142, 143, 144, and 145, such as copper, aluminum, or other conductive metal features exposed along a top side of the circuit board 140. The terminals 112, 121 and 131 of the electronic device 100 are electrically and mechanically connected to respective ones of the circuit board traces 141-145 by solder 146 (FIG. 1). In another example, the electronic device 100 can be installed in a socket (not shown) that is soldered to traces of the circuit board 140, with the device terminals 112, 121 and 131 engaging conductive terminals of the socket.

The solder or socket connection of the electronic device terminals 112, 121 and 131 provides electrical connection of the component or components of the semiconductor die 110 and the coils C1 and C2 in a circuit of the system circuit board 140, for example, to create a DC to DC converter. The integration of the metal structures 120 and 130 with the semiconductor die 110 in a single packaged electronic device 100 advantageously provides a modular integration of one or more die components with one or more magnetic components (e.g., coils C1 and C2) in a small compact arrangement, with the metal structures 120 and 130 facilitating low EMI emissions from the component(s) of the semiconductor die 110, and the circuit board design can be tailored to provide any desired interconnection of the integrated components of the electronic device 100.

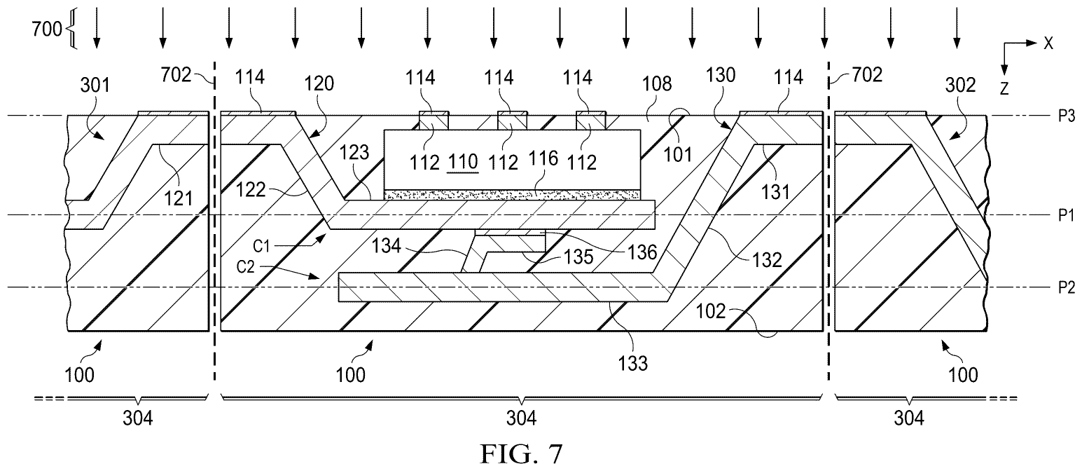

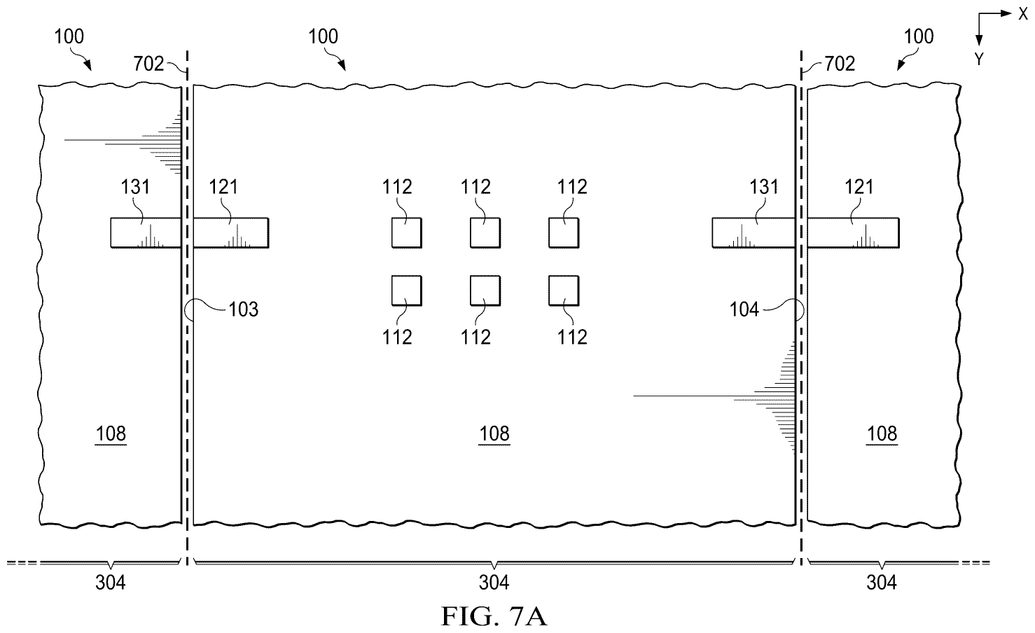

Referring to FIGS. 1, 1C and 1D, the internal electrical connection of internal ends of the coils C1 and C2, for example, by soldering the tab 134, 135 of the second metal structure 130 to the third portion 123 of the first metal structure 120 (FIG. 1C) provides an integrated inductor with externally exposed coil ends at the coil terminals 121 and 131 (FIG. 1D). The first coil terminal 121 in this example is connected to the circuit board trace 141 and the second coil terminal 131 is connected to the circuit board trace 142 (FIG. 1). In this example, moreover, the semiconductor die 110 includes first and second transistors T1 and T2 (FIG. 1D), with source, a gate, and drain connections to respective ones of the die terminals 112. The die terminals 112 of one of the transistors T1 and T2 are soldered to respective circuit board traces 143-145 as shown in FIG. 1, and the electronic device 100 in this example has further die terminals and exposed along the bottom or first side 101 that are connected to the terminals of the other transistor of the semiconductor die 110 (e.g., FIG. 7A below).

FIGS. 1E-1I show another example electronic device 150 with integrated first and second coils C1 and C2 that can be connected to form primary and secondary windings of a transformer and switching transistors in a semiconductor die 110. The electronic device 150 includes similarly numbered structures and features 101-106, 108, 110, 112, and 114 and is illustrated as being attached to a circuit board 140 with circuit board traces 141-145 that are the same or similar to similarly numbered structures and features described above in connection with FIGS. 1-1D except as described differently hereinafter or is differently shown in the drawings.

FIG. 1E schematically illustrates the electronic components of the electronic device 150. As shown in FIG. 1E, the coils C1 and C2 each have coil ends connected to respective coil terminals, and the coils C1 and C2 are magnetically coupled by the magnetic mold compound of the package structure 108 to provide operation as primary and secondary windings of an integrated transformer. In this case, the first end of the first coil C1 is connected to a coil terminal 161 and a second end of the first coil C1 is connected to a coil terminal 168. The second coil C2 has a first end connected to a coil terminal 171 and a second end connected to a coil terminal 178. The coil terminals 161, 168, 171, and 178 are exposed along the bottom side 101 of the electronic device 150 to allow soldering to corresponding traces of a host circuit board (e.g., FIG. 1F). In this example, moreover, the semiconductor die 110 includes first and second transistors T1 and T2 as shown in FIG. 1E, with corresponding source, a gate, and drain connections to respective die terminals 112 that can be soldered to respective circuit board traces.

In one system implementation, the electronic device 150 has an integrated transformer with a primary winding formed by the first coil C1 (FIGS. 1F, 1G, 1I, and 1E) and a secondary winding formed by the second coil C2 (FIGS. 1F and 1H-1E) integrated in a single package to conserve space and reduce cost in a power conversion system. FIG. 1F shows a side section view of the electronic device 150 taken along line 1F-1F of FIGS. 1G and 1H and FIG. 1G shows a top section view illustrating the first coil C1 along line 1G-1G of FIGS. 1F and 1I. FIG. 1H shows a top section view of the second coil C2 along line 1H-1H of FIGS. 1F and 1I. FIG. 1I shows a down set tab that attaches the two coils in a side section view along line 1I-1I of FIGS. 1G and 1H.

The molded magnetic package structure 108 of the electronic device 150 encloses portions of the first and second coils C1 and C2 and a portion of a semiconductor die 110 (FIG. 1F) and can be formed of magnetic molding compound to provide magnetic coupling for the coils C1 and C2. The die components and the integrated coils C1 and C2 have terminals 112, 161 and 171 that allow application-specific interconnection of the components in a desired circuit configuration by design of the host circuit board 140 and the conductive traces thereof. In one example, the circuit board 140 includes trace routings that connect the coil terminals 161 and 168 to a primary circuit (not shown), and separately connect the coil terminals 171 and 178 to a secondary circuit, with the coils C1 and C2 operating as primary and secondary windings of an integrated transformer. In another possible interconnection example, one of the coil terminals 161, 168 associated with the first coil C1 can be connected by circuit board routing to one of the coil terminals 171, 178 associated with the second coil C2, and the coils C1 and C2 can operate as a single integrated inductor.

The proximity of the semiconductor die 110 to metal structures 160 and 170 used in forming the coils C1 and C2 can help reduce electromagnetic interference (EMI) in operation of the electronic device 150 to provide improved inductance performance while reducing system cost and space. As shown in FIGS. 1F, 1G and 1I, the first coil C1 is formed by a first metal structure 160 with a first portion forming the first coil terminal 161 in a third plane P3, a second portion 162 that extends from the first portion 161 (FIG. 1F) to a third portion 163 in a parallel first plane P1 that includes the first coil C1. The first coil C1 has a first end that is electrically connected to the first coil terminal 161 by the second portion 162. As shown in FIGS. 1F, 1G, and 1I, the third portion 163 of the first coil C1 includes turns, and the turns of the first coil C1 extend within the first plane P1 indicated in FIGS. 1F and 1I. As further shown in FIGS. 1F, 1G and 1I, the first metal structure 160 further includes a portion 166 that extends from the second end of the first coil C1 downward from the first plane P1 to a final portion (FIGS. 1F and 1I) that forms a third coil terminal 168 that is exposed along the bottom or first side 101 of the electronic device 150 along the third plane P3. In this manner, the first coil terminal 161 is internally connected to a first end of the first coil C1, and the first metal structure 160 includes the third coil terminal 168 connected to the second end of the first coil C1, and the third coil terminal 168 is exposed outside the molded magnetic package structure 108 along the third plane P3.

As shown in FIGS. 1F, 1H and 1I, the electronic device 150 also has a second metal structure 170 with the second coil C2 extending in a second plane P2 that is approximately parallel to the first plane P1. The second metal structure 170 includes a first portion that forms the second coil terminal 171 along the third plane P3, a second portion 172 that extends from the first portion 171 to a third portion 173 in a second plane P2 (FIGS. 1F and 1I). The third portion 173 includes the second coil C2 in the second plane P2 with turns as shown in FIG. 1H. The example second metal structure 170 also includes fourth and fifth portions 174 and 175 (shown in FIG. 1I and shown in phantom lines in FIG. 1F) that form a downwardly extending tab (e.g., “down set” feature) of the second metal structure 170. The tab 174, 175 is connected to the first metal structure 160 (e.g., the first coil C1 of the third portion 163) by a non-conductive adhesive 176 (e.g., non-conductive die attach film or die attach material, such as epoxy) and the first and second coils C1, C2 are electrically isolated from one another to form a transformer unless externally connected to one another by circuit board trace routings. As further shown in FIGS. 1F, 1H, and 1I, the second metal structure 170 includes a further portion 177 that extends from the second end of the second coil C2 in the second plane P2 downward to a final portion in the third plane P3 to form a fourth coil terminal 178 connected to the second coil C2. The second coil terminal 171 of the electronic device 150 is connected to the first end of the second coil C2, the second metal structure 160 includes the fourth coil terminal 178 connected to a second end of the second coil C2, and the fourth coil terminal 178 is exposed outside the molded magnetic package structure 108 along the third plane P3.

The down set tab feature 174, 175 and the nonconductive adhesive 176 help position the first and second metal structures 160 and 170 along the third direction Z during manufacturing, as well as providing magnetic coupling of the first and second coils C1 and C2 to form an integrated transformer in the electronic device 150. In another example, the first and second metal structures 160 and 170 can be structurally attached to one another by an upset or down set feature (e.g., a tab) of one of the metal structures 160 or 170 that extends between the first and second planes P1 and P2 using nonconductive adhesive to magnetically couple the coils C1 and C2 to one another.

In another example, the relative positioning of the first and second metal structures 160 and 170 can be set during manufacturing by tab or other upset or down set features of starting first and second lead frames, which are removed during package separation after molding operations that form the magnetic molded package structure 108. For example, one or more tab structures can be provided in one or both of first and second starting lead frames which are used to connect the first and second lead frames (e.g., by soldering, conductive or non-conductive adhesive, etc.) to control the relative positions of the lead frames. In this example, the molding operations to form the package structure 108 hold the lead frame structures in their relative positions, and the upset and/or down set features of the lead frame or lead frames can be subsequently separated from the packaged electronic device 150 during package separation operations. In such examples, the tab 174, 175 can be omitted from the packaged electronic device 150, along with the adhesive 176. The relative positioning of the first and second metal structures 160 and 170 and the semiconductor die 110 provide approximately coplanar exposed surfaces of the terminals 112, 161 and 171 along the third plane P3 to provide electrical conductivity of the coils C1, C2 and the component or components of the semiconductor die 110 to the host circuit board 140.

FIG. 1J shows a power conversion system including another example electronic device 190 having three metal structures and three corresponding coils C1, C2, and C3 in a magnetic molded structure with exposed terminals soldered to a circuit board 140. The electronic device 190 includes similarly numbered structures and features 101-106, 108, 110, 112, and 114 and is illustrated as being attached to a circuit board 140 with circuit board traces 141-145 that are the same or similar to similarly numbered structures and features described above in connection with FIGS. 1-1D except as described differently hereinafter or is differently shown in the drawings. In various implementations, any integer number of two or more metal structures can be used, with extensions from corresponding parallel planes to the bottom plane of the electronic device (the third plane P3 in the illustrated example) The examples of FIGS. 1-1I included two metal structures (e.g., 120 and 130 in FIGS. 1-1D, and 160 and 170 in FIGS. 1D-1I).

The electronic device 190 in FIG. 1J includes the first metal structure 120 with the first coil C1 in the first plane P1, as well as the second metal structure 130 with the second coil C2 in the second plane P2 as described above in connection with FIGS. 1-1D. In addition, the electronic device 190 includes a third metal structure 180 having a first portion that forms a third coil terminal 181 exposed outside the molded magnetic package structure 108 along the bottom or first side 101 of the electronic device 190, as well as a second portion 182 that extends upward from the third plane P3 to a third portion 183 in a fourth plane P4 that is parallel with the first second and third planes P1-P3. In addition, the third portion 183 of the third metal structure 180 includes a coil structure with turns (not shown in the side view of FIG. 1J), with the second portion 182 connected to a first end of the third coil C3. The third portion 183 of the third metal structure 180 in this example also includes a downside tab feature including portions 184 and 185 that extend downward from the fourth plane P4 toward the second plane P2, and the tab feature 184, 185 is attached to the third portion 133 of the second metal structure 130 by solder or conductive adhesive 186.

In one implementation, the tab feature 184, 185 is connected to the second end of the third coil C3, and the coils C1-C3 are electrically connected in series to form an inductor between the first coil terminal 121 of the first metal structure 120 and the third coil terminal 181 of the third metal structure 180. This concept can be extended to any integer number of metal structures and associated coils, for example, to set an inductance of the integrated inductor. The height of the molded magnetic structure 108 can be adjusted during manufacturing to accommodate any desired number of coils, for example, using adjustable molding equipment (not shown). In other implementations, upset and/or down set features of any of the metal structures can be included or omitted, and where used can be connected using conductive or non-conductive adhesives or other suitable materials in order to selectively connect or isolate specific coils from one another, for example, to selectively provide inductors and/or transformer windings or other magnetic components integrated within a packaged electronic device along with one or more semiconductor dies. In addition, as discussed above, one or more upset and/or down set features can be provided in lead frame the bars or other locations that are ultimately cut or trimmed away during package separation operations, where upset and/or down set features may but need not be present in the finished packaged electronic device in various implementations.

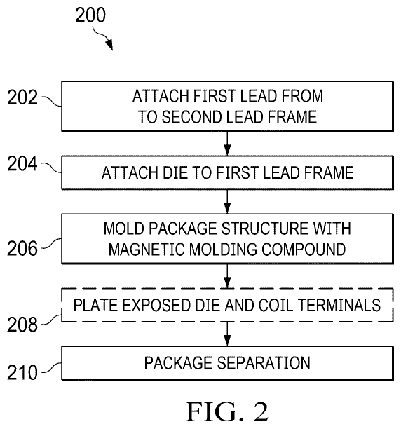

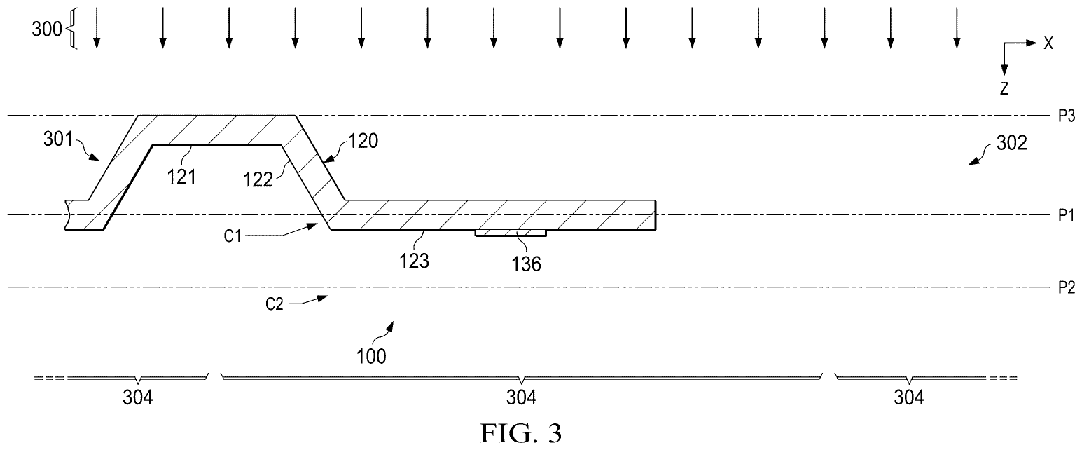

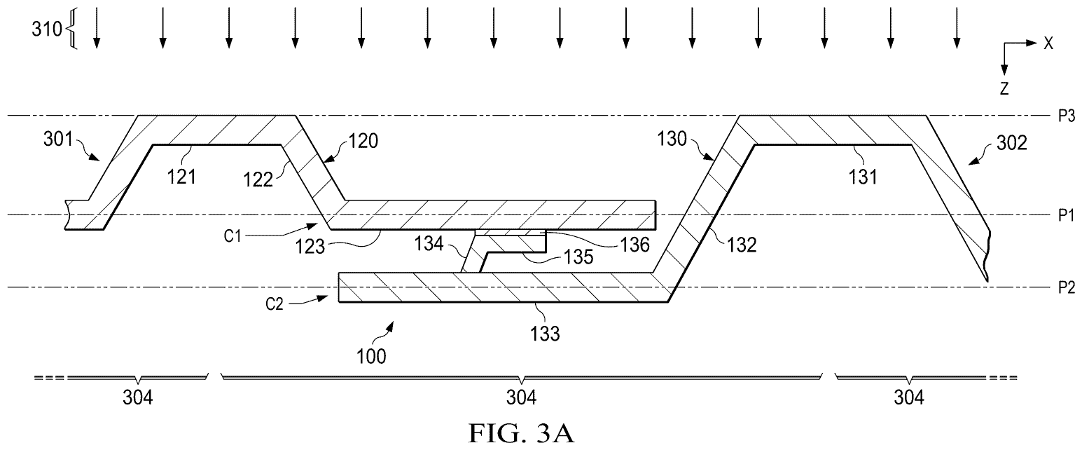

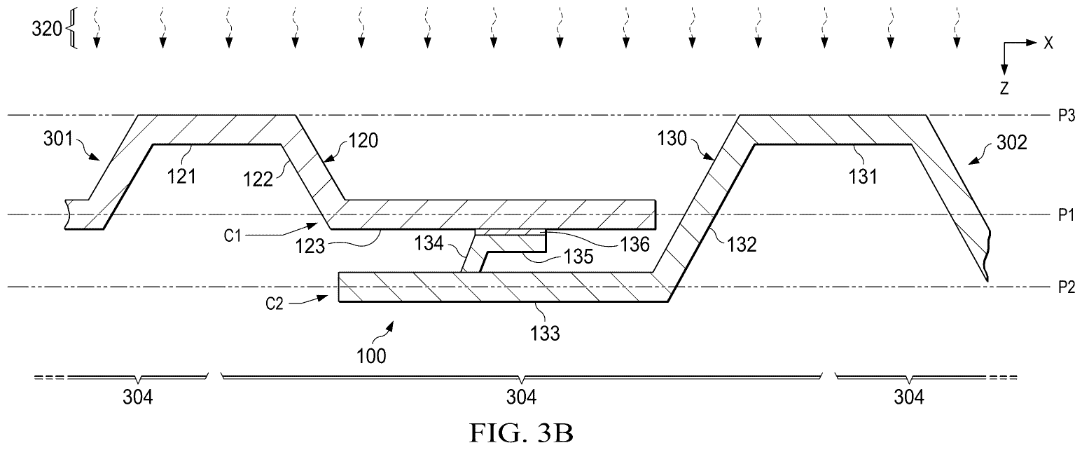

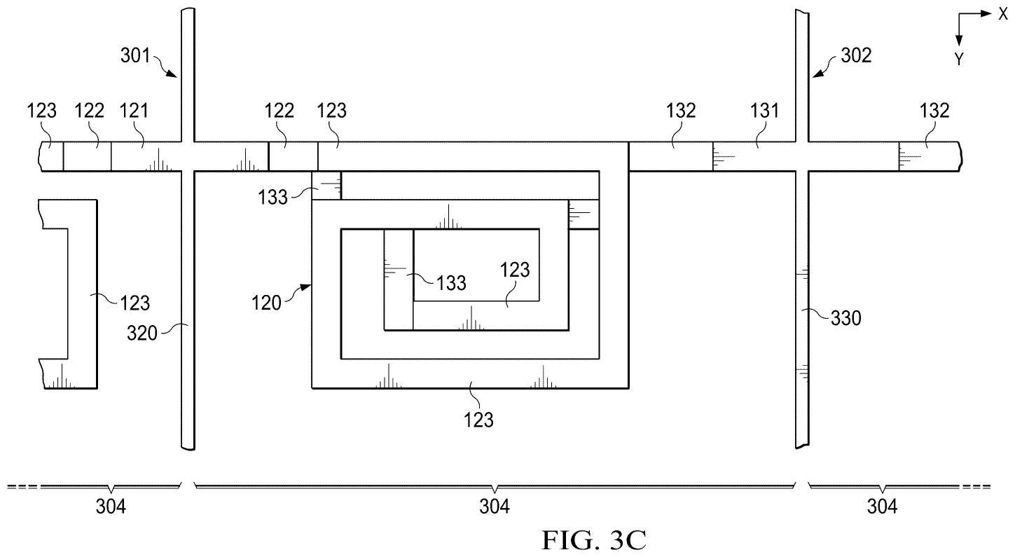

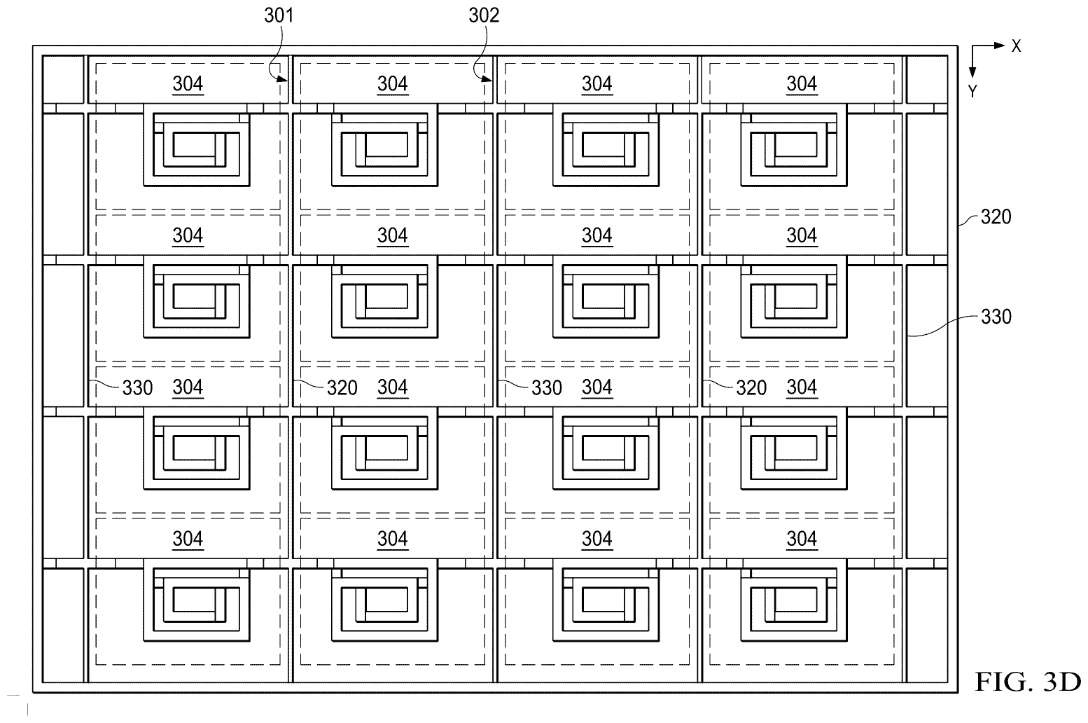

Referring to FIGS. 2-7A, FIG. 2 shows a method 200 for fabricating an electronic device and FIGS. 3-7A illustrate the example electronic device 100 of FIGS. 1-1D undergoing fabrication processing according to an example implementation of the method 200. The above described X-Y planes P1-P3 are shown in FIGS. 3-7A for reference.

The method 200 begins at 202 in FIG. 2 with attaching a first lead frame to a second lead frame. FIGS. 3-3B illustrate one example, in which a solder paste formation process 300 is performed that forms solder paste 136 on a select portion of a starting first lead frame 301. The first lead frame 301 includes multiple unit areas 304, for example, in an array structure with rows and columns of unit arrays 301. The individual unit areas 304 of the first lead frame 301 include copper or other suitable conductive metal features, with designated portions 121, 122 and 123 corresponding to subsequently separated first metal structures 120 in each unit area 304, with the lower side of the first lead frame 301 positioned along the above described third plane P3, for example, on a tape carrier or other suitable supporting structure (not shown), and the first coil C1 of the third portion 123 extending in the above described first plane P1. The solder paste formation process 300 can be a dispensing process, a printing process, a silk screening process, or other suitable process that selectively forms the solder paste 136 along a portion of a side of the third portion 123 of the first lead frame 301 to correspond to subsequently attached downside features of a second lead frame.

FIG. 3A shows an attachment process 310 that joins the third portion 123 of the first lead frame 301 in each unit area 304 to a down set tab feature 134, 135 of a second lead frame 302. The second lead frame 302 in this example also includes rows and columns of unit areas 304 that are aligned with the unit areas 304 of the first lead frame 301, and each unit area 304 of the second lead frame 302 includes the above-described portions and features 131-133 and the second coil C2 of the subsequently separated second metal structure 130. The attachment process 310 can be a manual or automated operation, for example, using automated positioning equipment and alignment features on the lead frames 301 and 302 and/or of an associated fixture (not shown). The attachment process 310 in one example attaches the lower portion 135 of the down set tab feature to the previously applied solder paste or adhesive 136. In one example, the lead frame attachment (e.g., 202 in FIG. 2) can include a thermal reflow process 320 as shown in FIG. 3B. The reflow process 320 in one example heats the lead frames 301 and 302 and reflows the solder 136 to form a solder connection of the first lead frame 301 to the second lead frame 302 in each of the unit areas 304 of the array structure. FIG. 3C shows a bottom view of the attached first and second lead frames 301 and 302, with the first and second coils C1 and C2 aligned in the first and second directions X and Y.

The attachment at 202 in FIG. 2 attaches the first and second lead frames 301 and 302 to one another with respective first and second coils C1 and C2 in respective first and second parallel planes P1 and P2. In another implementation, the lead frames 301 and 302 can be attached to one another using tabs or other upset or down set features (not shown) in tie bars or other portions of the lead frames 301 and 302 that are outside the unit areas 304. For example, the first lead frame 301 in FIG. 3C includes tie bars 301 that extend along the second direction Y between adjacent columns of unit areas 304, and the second lead frame 302 includes tie bars 330 that extend along the second direction Y between adjacent columns of unit areas 304.

As further shown in a bottom view of FIG. 3D, each lead frame 301 and 302 can include outer boundary tie bars that extend around and encircles the unit areas 304 (not shown in the view of FIG. 3C), which can include one or more upset and/or down set features (not shown) that can be used alternatively or in combination with tab features within the unit areas 304 of the array structure for attaching the first lead frame 301 to the second lead frame 302. Since the tie bars 320 and 330 are temporary or sacrificial and are not present in the ultimately separated packaged electronic devices, the upset and/or down set tab features of the tie bars 320 and 330 can be attached by any suitable conductive and/or nonconductive adhesive or other means in order to set the relative position of the first and second lead frames 301 and 302 and the coils C1 and C2 thereof along the vertical third direction Z until molding operations, after which the support features can be removed during package separation (e.g., unless desired for electrical connection of first and second coils within the unit areas 304). The lead frame attachment at 202 can include electrically connecting the coil C1 and C2 of the first and second lead frames 301 and 302, but electrical connection between is not required in all possible implementations, for example, where electrically isolated coils C1 and C2 may be used for primary and secondary windings of an integrated transformer (e.g., FIGS. 1E-1I above). In other implementations, nonconductive adhesive can be used to attach first and second lead frames to one another, and/or attachment can be made outside the unit areas 304 and/or combinations of lead frame connections within and outside the unit areas 304 can be used.

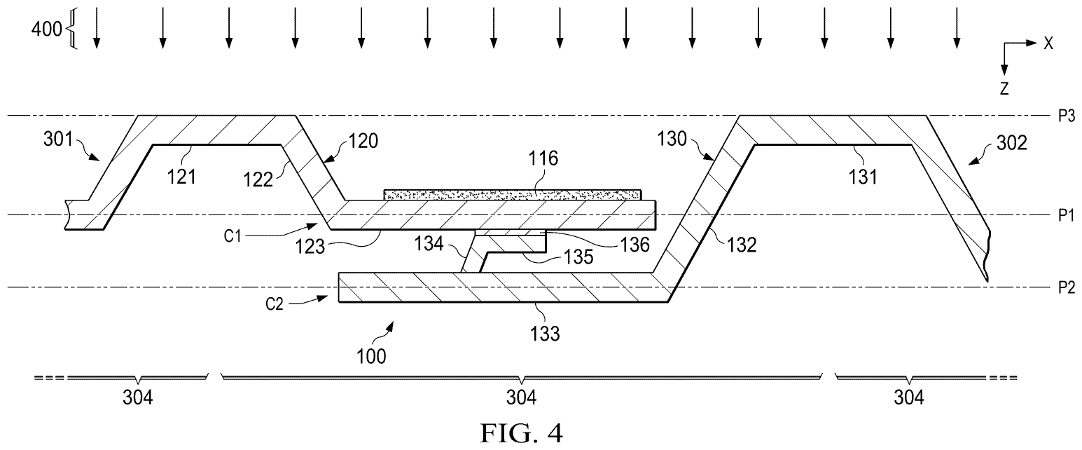

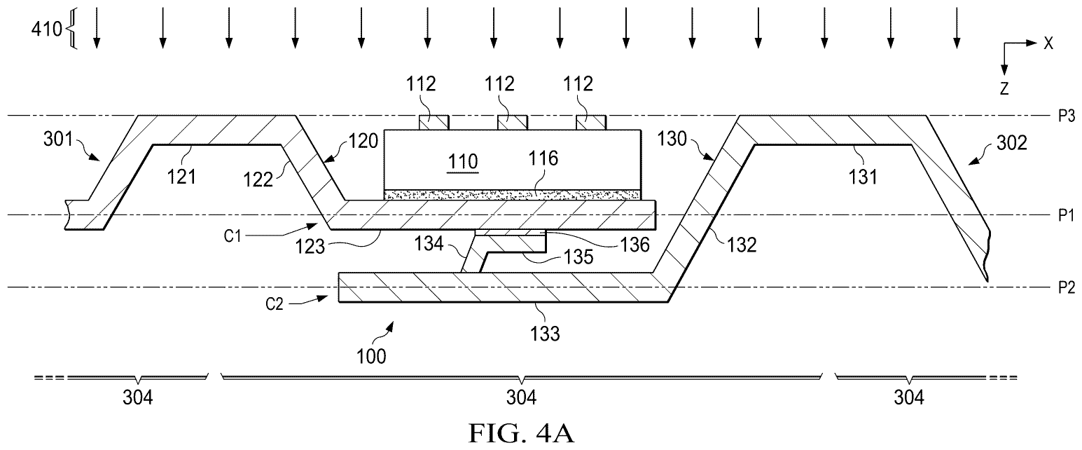

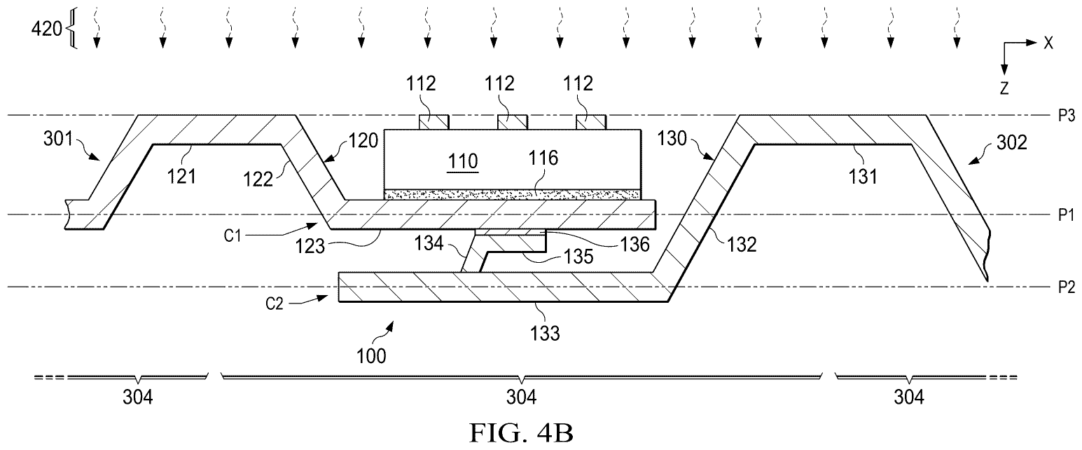

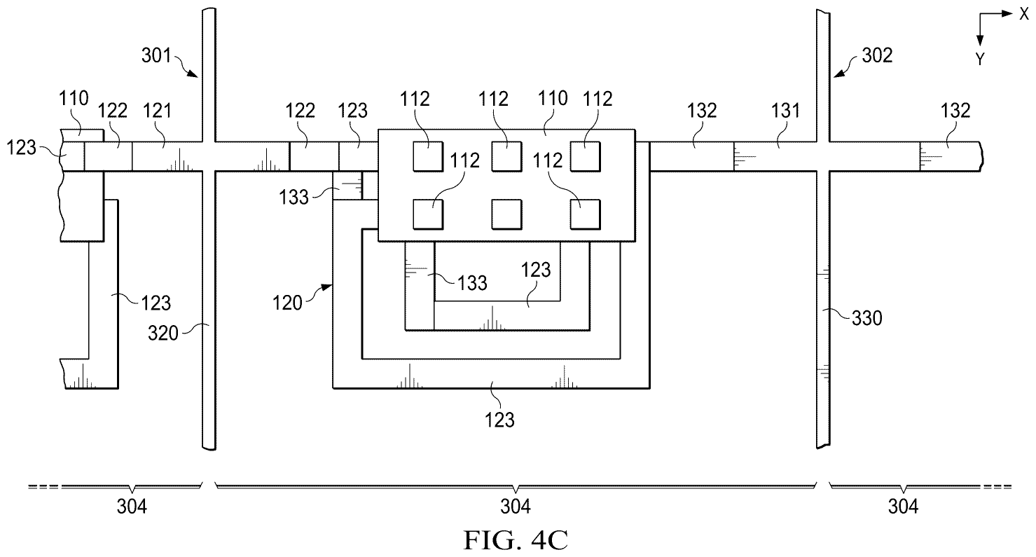

The method 200 continues at 204 in FIG. 2 with die attach processing to attach a semiconductor die to the first lead frame 304 in each unit area 304. FIG. 4 shows one example, in which a process 400 is performed that forms a nonconductive die attach material or other adhesive 116 to a select portion of the bottom side of the third portion 123 of the first lead frame 301 in each unit area 304. Any suitable process 400 can be used, such as a dispensing process, a printing process, a silk screening process, etc. A process 410 is performed in FIG. 4A in one example to attach the back side of a semiconductor die 110 to the first lead frame 301 in each unit area 304, for example, with the back side of the semiconductor die 110 attached to the bottom of the first coil C1. In one example, the attachment at 204 in FIG. 2 can also include a curing step to cure the adhesive 116. FIG. 4B shows one example, in which a curing process 420 is performed that cures the die attach adhesive 116 in each unit area 304. Any suitable adhesive curing process 420 can be used, for example, thermal, ultraviolet light exposure, etc. FIG. 4C shows a bottom view, with an instance of the semiconductor die 110 attached in each unit area 304 of the array structure, with the die terminals 112 extending out of the front side of the semiconductor die 110.

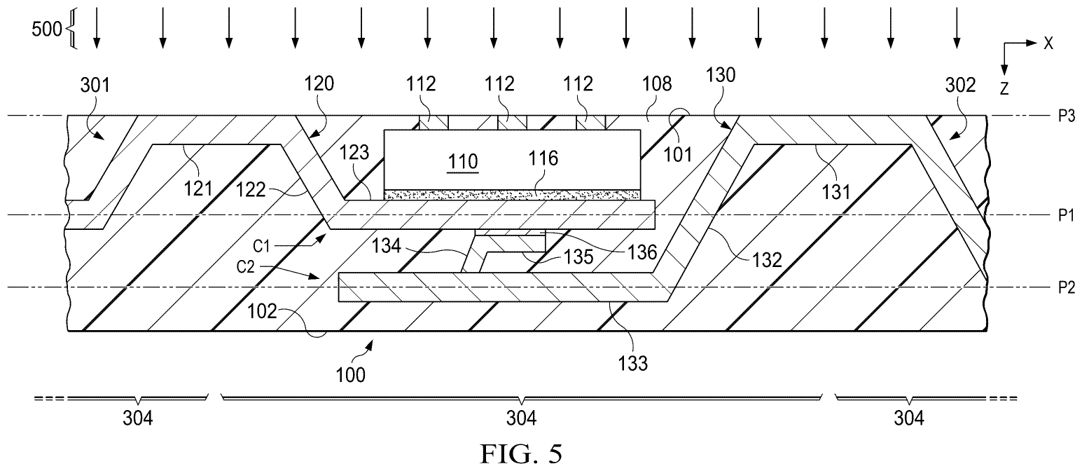

The method 200 continues at 206 and FIG. 2 with molding a magnetic package structure using magnetic molding compound. FIG. 5 shows one example, in which a molding process 500 is performed using magnetic molding compound to form a molded magnetic package structure 108. In one example, a single mold cavity can be used to form a unitary magnetic molded structure 108 that extends across all the rows and columns of the panel array structure. In another implementation, the individual mold cavities can be used to form respective molded magnetic package structures 108 in each unit area 304. In other implementations, the individual mold cavities can extend across two or more unit areas 304 of the array structure, for example, to form magnetic molded package structures 108 along rows or columns of the array structure. The molding process 500 in one example molds the magnetic package structure 108 to enclose the first and second coils C1 and C2 and a portion of the semiconductor die 110 in each unit area 304 and to expose die terminals 112 of a front side of the semiconductor die 110 and first and second coil terminals of the first and second lead frames 301 and 302 outside the molded magnetic package structure 108 along the third plane P3.

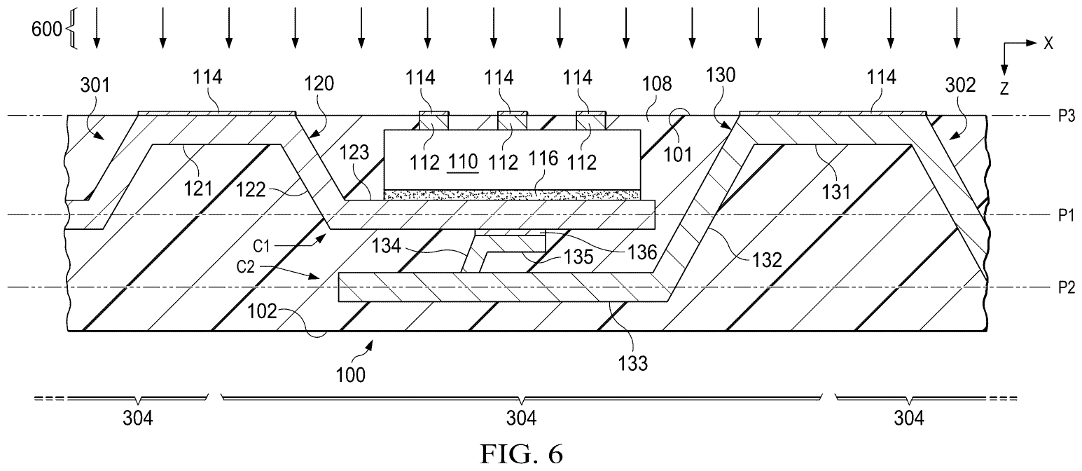

The method 200 continues in one example at 208 in FIG. 2 with optional post molding plating operations. FIG. 6 shows one example, in which an electroplating process 600 is performed that forms plates exposed surfaces of the die terminals 112 and the coil terminals 121, 131 along the third plane P3 to create the plated surfaces 114 thereof. In another example, the plating at 208 in FIG. 2 can be omitted.

The method 200 continues at 210 in FIG. 2 with package separation. FIG. 7 shows one example, in which a package separation process 700 is performed that separates individual packaged electronic devices 100 from the rows and columns of the panel array structure along lines 702. In one example, the package separation process 700 removes all or portions of the tie bars (e.g., FIGS. 3C, 3D, and 4C above), which are not present in the separated packaged electronic devices 100. Any suitable package separation process 700 can be used, for example, saw cutting, laser cutting, chemical etching, etc., or combinations thereof. FIG. 7A shows a bottom view of a portion of the array structure following package separation, showing the die and coil terminals 112, 121, 131 exposed outside the bottom side of the molded magnetic package structure 108 in each unit area 304.

Modifications are possible in the described examples, and other implementations are possible, within the scope of the claims.

What is claimed is:

1. An electronic device, comprising:
a first metal structure with a first coil extending in a first plane and a first coil terminal;
a second metal structure with a second coil extending in a second plane and a second coil terminal, the second plane approximately parallel to the first plane;
a semiconductor die with die terminals and opposite first and second sides, the first side attached to the first metal structure and the die terminals extending outward from the second side to a parallel third plane; and
a molded magnetic package structure enclosing portions of the first and second coils and a portion of the semiconductor die, wherein the die terminals and the first and second coil terminals are exposed outside the molded magnetic package structure along the third plane.

2. The electronic device of claim 1, wherein the first metal structure is attached to the second metal structure by a tab of one of the first and second metal structures.

3. The electronic device of claim 2, wherein the tab electrically connects the first coil to the second coil to form an inductor between the first and second coil terminals.

4. The electronic device of claim 3, wherein the tab is connected to the other of the first and second metal structures by solder.

5. The electronic device of claim 2, wherein the tab is connected to the other one of the first and second metal structures by a non-conductive adhesive and the first and second coils are electrically isolated from one another to form a transformer.

6. The electronic device of claim 5, wherein:
the first coil terminal is connected to a first end of the first coil;
the first metal structure includes a third coil terminal connected to a second end of the first coil;
the second coil terminal is connected to a first end of the second coil;
the second metal structure includes a fourth coil terminal connected to a second end of the second coil; and
the third and fourth coil terminals are exposed outside the molded magnetic package structure along the third plane.

7. The electronic device of claim 1, wherein the die terminals and the coil terminals have respective plated surfaces exposed outside the molded magnetic package structure along the third plane.

8. A system, comprising:
a circuit board having a conductive trace; and
an electronic device, comprising first and second metal structures, a semiconductor die, and a molded magnetic package structure, the first metal structure having a first coil extending in a first plane and a first coil terminal, the second metal structure having a second coil extending in a second plane and a second coil terminal, the second plane approximately parallel to the first plane, the semiconductor die having die terminals and opposite first and second sides, the first side attached to the first metal structure and the die terminals extending outward from the second side to a parallel third plane, and the molded magnetic package structure enclosing portions of the first and second coils and a portion of the semiconductor die, wherein the die terminals and the first and second coil terminals are exposed outside the molded magnetic package structure along the third plane and are attached to respective ones of the conductive traces.

9. The system of claim 8, wherein the first metal structure is attached to the second metal structure by a tab of one of the first and second metal structures.

10. The system of claim 9, wherein the tab electrically connects the first coil to the second coil to form an inductor between the first and second coil terminals.

11. The system of claim 10, wherein the tab is connected to the other of the first and second metal structures by solder.

12. The system of claim 9, wherein the tab is connected to the other one of the first and second metal structures by a non-conductive adhesive and the first and second coils are electrically isolated from one another to form a transformer.

13. A method of fabricating an electronic device, the method comprising:
attaching first and second lead frames to one another with respective first and second coils in respective first and second parallel planes;
attaching a semiconductor die backside to the first coil; and
molding a magnetic package structure to enclose the first and second coils and a portion of the semiconductor die and to expose die terminals of a front side of the semiconductor die and first and second coil terminals of the first and second lead frames outside the molded magnetic package structure along a third plane that is parallel to the first and second planes.

14. The method of claim 13, wherein attaching the first and second lead frames to one another includes electrically coupling the first and second coils to one another.

15. The method of claim 13, wherein attaching the first and second lead frames to one another includes soldering a tab of one of the first and second lead frames to a portion of the other one of the first and second lead frames.

16. The method of claim 13, wherein attaching the first and second lead frames to one another includes adhering portions of the first and second lead frames using a non-conductive adhesive.

17. The method of claim 13, wherein:
the first and second lead frames each include rows and columns of unit areas (304) and tie bars outside the unit areas; and
attaching the first and second lead frames to one another includes attaching a tab of a tie bar of one of the first and second lead frames to a portion of a tie bar of the other one of the first and second lead frames to form a panel array.

18. The method of claim 17, further comprising, after molding the magnetic package structure includes cutting the tie bar to separate an electronic device from the panel array.

19. The method of claim 13, further comprising attaching a third lead frame to one of the first and second lead frames a third coil of the third lead frame in a fourth plane that is parallel to the first and second planes.

20. The method of claim 13, further comprising, after molding the magnetic package structure, plating exposed surfaces of the die terminals and the coil terminals.
